(19) United States
(12) Patent Application Publication
(10) Pub. No.: US 2006/0193361 A1
(43) Pub. Date: Aug. 31, 2006

(54) Vertical cavity surface emitting laser device having a higher optical output power

(75) Inventors: Setiagung Casimirus, Tokyo (JP); Takeo Kageyama, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: THE FURUKAWA ELECTRIC CO., LTD., Tokyo (JP)

(21) Appl. No.: 11/347,225

(22) Filed: Feb. 6, 2006

(30) Foreign Application Priority Data
Feb. 9, 2005 (JP) 2005-032787

(51) Int. Cl. H01S 3/14; H01S 5/20; H01S 5/00; H01S 3/08; H01S 5/323

(52) U.S. Cl. 372/68; 372/103; 372/46.01; 372/45.01

(57) ABSTRACT

A vertical cavity surface emitting laser (VCSEL) device includes has an epitaxial layer structure formed on a GaAs substrate and including a pair of multilayer reflectors and a tunnel junction structure. The tunnel junction structure is configured by a heavily-doped n-type Tiₓ₂Inₓ₁Ga₁₋ₓ₁₋ₓ₂As_{1-y1-y2}N_{y1}Sb_{y2} mixed-crystal layer and a heavily-doped p-type Tiₓ₄Inₓ₃Ga₁₋ₓ₃₋ₓ₄As_{1-y3-y4}N_{y3}Sb_{y4} mixed-crystal layer, where 0≦x2≦0.3, 0≦x1≦0.3, 0<y1≦0.05, 0<y2≦0.3, 0≦x4≦0.3, 0≦x3≦0.05, 0<y3≦0.05, and 0<y4≦0.3.

### TECHNICAL FIELD

The present invention relates to a vertical cavity surface emitting laser (VCSEL) device.

### BACKGROUND ART

VCSEL devices have advantages that a plurality of VCSEL devices can be arranged in a two dimensional array on a single common substrate and operate with a lower threshold current, and thus are suited for use in the field of optical interconnection, optical computing and optical communication.

The VCSEL devices can be manufactured at a lower cost and are now to replace the DFB (distributed feedback) laser devices which have been used heretofore as a light source in the fields of middle- to long-distance optical communications. For the purpose of application in these fields, it is necessary to develop an improved VCSEL device having a longer emission wavelength of 0.85 μm or longer and capable of lasing in a single transverse mode.

A long-wavelength-range VCSEL device having a GaInNAs quantum well layer and lasing at a wavelength of 1.2 μm or longer now attracts a larger attention. The GaInNAs achieves a suitable lattice matching with GaAs and AlGaAs, unlikely from the other optical materials for the long-wavelength-range VCSEL devices. This lattice matching property allows a substrate used for the epitaxial growth and a multilayer reflector to be manufactured from the materials generally used in manufacturing 0.85-μm-range VCSEL devices which are already in practical use.

In a typical semiconductor laser device, the p-n junction sandwiching the active layer is biased to pass a forward current, which injects carriers into the active layer for optical emission using injection excitation. In the case of the VCSEL device, this injection excitation is generally performed by using a pair of multilayer reflectors including p-type and n-type semiconductor reflectors.

In a 0.85-μm-range VCSEL device, since p-type AlGaAs used as the material for the p-type semiconductor reflector incurs a large optical loss due to absorption in the valence band, the p-type AlGaAs has a disadvantage in the optical output power if used in a long-wavelength-range VCSEL device, in which the active layer generally suffers from a lower lasing power. In particular, the problem therein is that a higher ambient temperature markedly reduces the optical output power.

There is a countermeasure for the above problem by using a tunnel junction structure. The tunnel junction structure is such that the doping-impurity density in the materials for the p-n junction is selected extremely higher so that even a backward bias applied across the p-n junction allows a large current to pass thereacross by the tunnel junction. This is because the electrons in the valence band of the p-type region moves to the conduction band of the n-type region due to the tunnel effect. Use of the tunnel junction in the VCSEL device has an advantage that the multilayer reflector is configured without using the p-type AlGaAs. The conventional VCSEL device using the tunnel junction will be described in detail hereinafter.

FIG. 6A shows a conventional tunnel unction VCSEL device including n-type AlGaAs in the bottom multilayer reflector as well as in the top multilayer reflector. The VCSEL device generally designated by numeral 200 includes an n-type GaAs (referred to as n-GaAs hereinafter) substrate 2, and an epitaxial layer structure including an n-GaAs/AlGaAs bottom multilayer semiconductor reflector 3, an n-GaAs lower cladding layer 4, a multiple-quantum-well (MQW) active layer structure 5, a p-GaAs upper cladding layer 6, a p-GaAs/AlGaAs multilayer film 7, tunnel junction layers 10, and an n-GaAs/AlGaAs top multilayer semiconductor reflector 11, which are deposited on the n-GaAs substrate 1 in this order. An AlGaAs layer or layers within the p-type multilayer film 7 is configured by oxidation of Al to have a peripheral oxide (AlₓO_{y}) region 8b and a central non-oxide region 8a, or oxide aperture, which defines an optical emission region. An annular top electrode 12 and a bottom electrode 13 are provided on top an bottom, respectively, of the laser device.

The tunnel junction layers 10 are such that a p⁺⁺-type layer 10a and an n⁺⁺-type layer 10b are consecutively deposited from the bottom, wherein p⁺⁺- and n⁺⁺-type layers mean p- and n-type heavily-doped layers.

In operation of the VCSEL device 200 having the tunnel junction shown in FIG. 6A, the n-GaAs substrate 2 is applied with a negative voltage so that a portion of the layer structure including the n-type bottom multilayer semiconductor reflector 3/active layer structure 5/p⁺⁺-type layer 10a is forward biased and another portion of the layer structure including the p⁺⁺- type layer 10a/n⁺⁺-type layer 10b is backward biased to inject carriers into the active layer structure 5. The structure wherein the tunnel junction allows injection of carriers into the active layer structure 5 without using the p-AlGaAs in the multilayer reflector provides the advantages of smaller absorption in the valence band, higher optical output power and superior temperature characteristics.

FIG. 6B shows another conventional tunnel-junction VCSEL device 200A including n-AlGaAs in the bottom multilayer reflector 3 and a dielectric material in the top multilayer reflector 17. Similar constituent elements are designated by similar reference numerals in FIGS. 6A and 6B. The VCSEL device 200A of FIG. 6B includes a contact layer and an electrode on a portion of the active layer structure to configure a so-called intra-cavity contact structure.

More specifically, the VCSEL device 200A includes a GaAs substrate 2 and an epitaxial layer structure including an n-GaAs/AlGaAs bottom multilayer semiconductor reflector 3, an n-GaAs lower cladding layer 4, a MQW active layer structure 5, a p-GaAs upper cladding layer 6, a p-AlGaAs/GaAs multilayer film 7, tunnel junction layers 10 and an n-GaAs contact layer 14, which are deposited in this order on the n-GaAs substrate 2. On top of the n-GaAs contact layer 14 are provided a top multilayer dielectric reflector 17 configuring a central emission region and an annular top electrode 12 encircling the central emission region. The bottom of the n-GaAs substrate 2 is provided with a bottom electrode 13. In the structure of the intra-cavity contact structure shown in FIG. 6B, current can be injected into the active layer structure 5 without using the p-AlGaAs multilayer reflector, thereby also achieving the advantages of smaller absorption in the valence band, higher optical output power and superior temperature characteristics.

US Patent Application Publication 2004/0051113A1 describes an example of the conventional long-wavelength-range VCSEL device having tunnel junction layers including an n⁺⁺-GaInNAs layer and a p⁺⁺-InGaAsSb layer.

### DISCLOSURE OF THE INVENTION

### PROBLEMS TO BE SOLVED BY THE INVENTION

In the VCSEL device described in the above patent publication, wherein the tunnel junction layers include n⁺⁺-GaInNAs and p⁺⁺-InGaAsSb layer, there is a problem in that the N included in the n⁺⁺-GaInNAs layer degrades the crystallinity of the tunnel junction layers, and that the large difference in the lattice constants between the p⁺⁺-InGaAsSb layer and the n⁺⁺-GaInNAs layer incurs a residual strain in the tunnel junction layers. Thus, such a structure of the tunnel junction degrades the reliability of the VCSEL device.

In the conventional tunnel-junction VCSEL devices shown in FIGS. 6A and 6B, there is a problem in that the AlₓO_{y} oxide region 8b increases the intra-surface refractive-index difference, i.e., the difference in the refractive index as viewed in the direction normal to the laser emission direction. More specifically, the AlₓO_{y} region has a refractive index extremely lower than the refractive index of the GaAs-based semiconductor materials, increases the light confinement function to cause a higher-order mode lasing, and obstacles the single-mode transverse lasing. It may be considered here that a smaller diameter of the oxide aperture provides the single-mode transverse lasing; however, it prevents a higher optical output power and thus is undesirable.

In view of the above problems in the conventional techniques, it is an object of the present invention to provide a long-wavelength-range VCSEL device having a higher optical output power and superior temperature characteristics while achieving a single-mode transverse lasing and a higher reliability.

### MEANS FOR SOLVING THE PROBLEMS

The present invention provides, in a first aspect thereof, a vertical cavity surface emitting semiconductor laser (VCSEL) device including a GaAs substrate, and an epitaxial layer structure including a bottom multilayer reflector, an active layer, and a top multilayer reflector consecutively deposited on the GaAs substrate,

the layer structure further including tunnel junction layers including a heavily-doped n-type Tiₓ₂Inₓ₁Ga₁₋ₓ₁₋ₓ₂As_{1-y1-y2}N_{y1}Sb_{y2} mixed-crystal layer and a heavily-doped p-type Tiₓ₄Inₓ₃Ga₁₋ₓ₃₋ₓ₄As_{1-y3-y4}N_{y3}Sb_{y4} mixed-crystal layer, where 0≦x2≦0.3, 0≦x1≦0.3, 0<y1≦0.05, 0<y2≦0.3, 0≦x4≦0.3, 0≦x3≦0.05, 0<y3≦0.05, and 0<y4≦0.3.

The present invention also provides, in a second aspect thereof, a vertical cavity surface emitting semiconductor laser (VCSEL) device including a GaAs substrate, and an epitaxial layer structure including a bottom multilayer reflector, an active layer, a current confinement layer and a top multilayer reflector consecutively deposited on the GaAs substrate,

the current confinement layer including a light-emitting aperture and a current-blocking region encircling the light-emitting aperture, the light-emitting aperture including tunnel junction layers including a heavily-doped n-type layer and a heavily-doped p-type layer, wherein a difference in an effective refractive index between the light-emitting aperture and the current-blocking region is equal to or below 0.5.

It is preferable that the VCSEL device according to the second aspect of the present invention have a configuration wherein the heavily-doped n-type layer includes a Tiₓ₂Inₓ₁Ga₁₋ₓ₁₋ₓ₂As_{1-y1-y2}N_{y1}Sb_{y2} mixed crystal, the heavily-doped p-type layer includes a Tiₓ₄Inₓ₃Ga₁₋ₓ₃₋ₓ₄As_{1-y3-y4}N_{y3}Sb_{y4} mixed crystal, and the current-blocking region includes GaAs_{1-y5-y6}N_{y5}Sb_{y6}, where 0≦x2≦0.3, 0≦x1≦0.3, 0<y1≦0.05, 0<y2≦0.3, 0≦x4≦0.3, 0≦x3≦0.05, 0<y3≦0.05, 0<y4≦0.3, 0≦y5≦0, and 0≦y6≦0.3.

It is also preferable that the VCSEL device according to the second aspect of the present invention have a configuration, wherein the light-emitting aperture further includes a graded-composition layer and a refractive-index adjustment layer consecutively deposited on the tunnel junction layers, the graded-composition layer includes Al_{z1}Ga_{1-z1}As_{1-w1-w2-w3}N_{w1}Sb_{w2}P_{w3} mixed crystal, and the refractive-index adjustment layer includes In_{z3}Ga_{1-z3}P mixed crystal, where 0≦z1≦0.6, 0≦w1≦0.05, 0≦w2≦0.3, 0≦w3≦0.8, and 0.3≦z3≦0.7.

It is also preferable that the VCSEL device according to the second aspect of the present invention have a configuration wherein the light-emitting aperture further includes a graded-composition layer and a refractive-index adjustment layer consecutively deposited on the tunnel junction layers, the graded-composition layer includes In_{z1}Ga_{1-z1}As_{1-w1-w2-w3}N_{w1}Sb_{w2}P_{w3} mixed crystal, and the refractive-index adjustment layer includes GaAs_{1-w4}P_{w4} mixed crystal, where 0≦z1≦0.3, 0≦w1≦0.05, 0≦w2≦0.3, 0≦w3≦0.8, and 0≦w4≦0.5.

It is preferable that the VCSEL devices of the first and second aspect of the present invention have a configuration wherein at least one of layers in the bottom multilayer reflector and top multilayer reflector is an undoped semiconductor layer. In an alternative, the undoped semiconductor layer may be replaced by a dielectric film.

In accordance with the VCSEL device of the present invention, since the tunnel junction layers have a superior crystallinity and a reduced residual strain, a long-wavelength-range VCSEL device having a higher reliability can be obtained. In addition, since the band profile of the tunnel junction layers can be optimized, the resultant VCSEL device has a lower device resistance and superior temperature characteristics. Moreover, a larger diameter can be employed for the emission aperture without degrading the single-mode transverse lasing characteristic, thereby providing a VCSEL device having a higher optical output power/

### BRIEF DESCRIPTION OF HE DRAWINGS

FIG. 1 is a longitudinal-sectional view of a VCSEL device according to first and second embodiments of the present invention.

FIG. 2 is a graph showing the relationship between the bandgap energy of a variety of compound semiconductors and the lattice constant thereof.

FIG. 3A is a longitudinal-sectional view of a VCSEL device according to a third embodiment of the present invention, and FIG. 3B is an enlarged partial view thereof.

FIG. 4A is a longitudinal-sectional view of a VCSEL device according to fourth and fifth embodiments of the present invention, and FIG. 4B is an enlarged partial view thereof.

FIG. 5 is a graph showing the relationship between the thickness of the refractive-index adjustment layer and the single-mode radius.

FIGS. 6A and 6B each show a longitudinal-sectional view of a conventional tunnel-junction VCSEL device.

### EMBODIMENTS OF THE INVENTION

Now, the present invention will be further described in detail with reference to accompanying drawings, wherein similar or corresponding constituent elements are designated by similar reference numerals throughout the drawings.

### First Embodiment

The first embodiment of the present invention is directed to a tunnel-junction VCSEL device of an oxidized-confinement type having an emission wavelength of 1290 nm and including an oxide aperture.

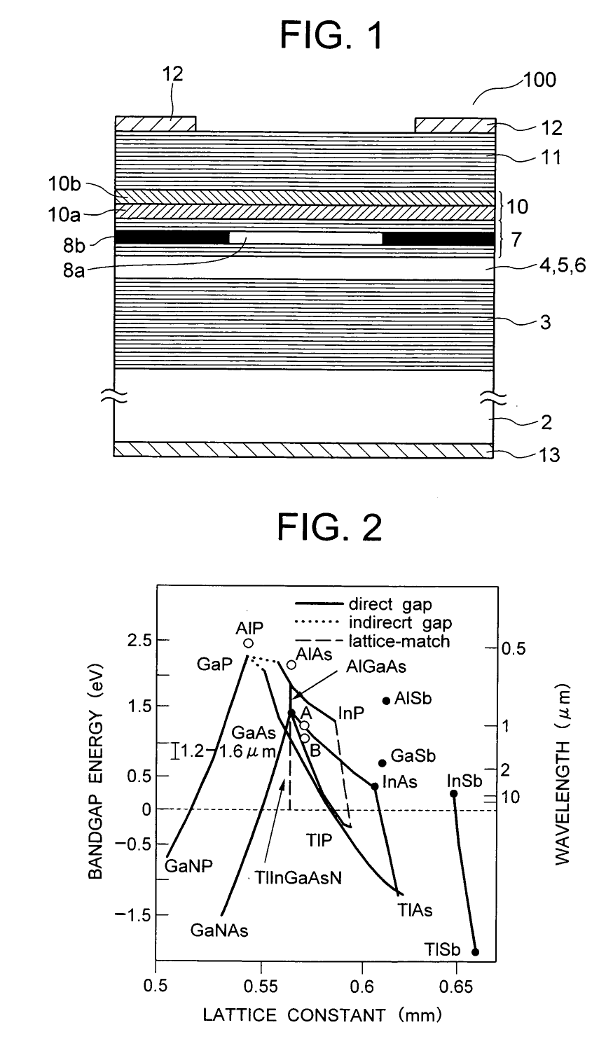

FIG. 1 shows a longitudinal-sectional view of the VCSEL device of the first embodiment. The VCSEL device 100 includes an n-GaAs substrate 2, and an epitaxial layer structure including an n-type bottom multilayer semiconductor reflector 3, a 125-nm-thick n-GaAs lower cladding layer 4, a MQW active layer structure 5, a 125-nm-thick p-GaAs upper cladding layer 6, p-type multilayer film 7, tunnel junction layers 10, a top multilayer semiconductor reflector 11, which are consecutively deposited on the n-GaAs substrate 2.

The n-type bottom multilayer reflector 3 includes n-Al_{0.9}Ga_{0.1}As layers and n-GaAs layers each having a thickness of ¼ optical length and alternately deposited in pair to form 35 layer pairs. The MQW active layer film 5 includes a plurality of 6-nm-thick quantum well Ga0.68In_{0.32}N_{0.01}As_{0.09} layers and a plurality of GaNAs barrier layers sandwiched between adjacent two of the quantum well layers. The p-type multilayer film 7 includes p-Al_{0.9}Ga_{0.1}As layers and p-GaAs layers each having a thickness of ¼ optical length and alternately deposited in pair to form two layer pairs. The top multilayer semiconductor reflector 11 includes n-Al_{0.9}Ga_{0.1}As layers and n-GaAs layers each having a thickness of ¼ optical length and alternately deposited in pair to form 20 layer pairs. An Al_{0.9}Ga_{0.1}As layer or layers in the p-AlGaAs/AlGaAs multilayer film 7 is replaced by AlAs layer or layers, which is configured by oxidation to form a current confinement structure including a central non-oxide region 8a, i.e., current-injection region, and a peripheral AlₓO_{y} region 8b, i.e., current-blocking region which surrounds the current injection region.

A Cr/Au bottom electrode 13 and a Cr/Au top electrode 12 are formed on the bottom of the n-GaAs substrate 2 and top of the top multilayer semiconductor reflector 11, respectively.

The tunnel junction layers 10 include a p⁺⁺-In_{0.1}Ga_{0.9}As_{0.945}N_{0.005}Sb_{0.05} layer 10a doped with carbon at a concentration of 1×10²⁰ cm⁻³ and an n⁺⁺-In_{0.06}Ga_{0.94}As_{0.975}N_{0.02}Sb_{0.005} 10b doped with silicon at a concentration of 1×10¹⁹ cm⁻³. The p⁺⁺-type layer 10a is in contact with the underlying p-type multilayer film 7.

The Sb included in both the n⁺⁺- and p⁺⁺-type layers 10b, 10a of the tunnel junction layers 10 improves the crystallinity due to the surfactant effect thereof during deposition of the tunnel junction layers 10b, 10a. The N included in both the n⁺⁺- and p⁺⁺-type layers 10b, 10a reduces the residual strain in the tunnel junction layers 10.

The composition of the InGaAsNSb in both the n⁺⁺- and p⁺⁺-type layers 10ab, 10a is not necessarily limited to the above ratio and may be selected as desired, so long as the In component in the III-group elements is between 0 and 0.3, the N component and Sb component in the V-group elements is between 0 and 0.05 and between 0 and 0.3, respectively. The reason for limiting to such a composition is to reduce the absorption loss of the light component having a wavelength of 1.25 μm or longer within the tunnel junction layers 10 to a minimum. The thickness in total of the n⁺⁺- and p⁺⁺-type layers 10b, 10a of the tunnel junction layers 10 is preferably 60 nm or smaller for reducing the absorption loss caused by the carriers.

The VCSEL device 100 of the present embodiment may be manufactured using a technique generally used for the conventional VCSEL devices. For example, the bottom multilayer reflector 3, lower cladding layer 4, upper cladding layer 6, p-type multilayer film 7 and top multilayer semiconductor reflector 11 may be formed using metal-organic chemical vapor deposition (MOCVD), whereas the MQW active layer structure 5 and tunnel junction layers 10 may be formed using molecular beam epitaxy (MBE).

The tunnel junction structure employed in the VCSEL device 100 of the present embodiment affords a higher optical output power due to absence of the p-AlGaAs layer which generally causes absorption in the valence band thereof. In addition, the Sb included in both the n⁺⁺- and p⁺⁺-type layers 10b, 10a of the tunnel junction layers 10 improves the crystallinity of, in particular, the p⁺⁺-type layers 10a compared to the conventional tunnel-junction VCSEL device. Further, the N included in both the n⁺⁺- and p⁺⁺-type layers 10b, 10a reduces the residual strain of, in particular, the n⁺⁺-type layer 10b compared to the conventional tunnel-junction VCSEL devices. Thus, the present embodiment provides a VCSEL device having a higher optical output power and a superior long-term reliability.

### Second Embodiment

The second embodiment of the present invention is directed to a tunnel-junction VCSEL device of an oxidized-confinement type having an emission wavelength of 1300 nm. The VCSEL device of the present embodiment is similar to the first embodiment except for the composition of the tunnel junction layers, and thus will be also described with reference to FIG. 1.

The tunnel junction layers 10 in the present embodiment includes a p⁺⁺-Ti_{0.02}In_{0.02}Ga_{0.96}As_{0.945}N_{0.005}Sb_{0.05} layer 10a doped with carbon at a concentration of 1×10²⁰ cm⁻³ and an n⁺⁺-Ti_{0.02}In_{0.02}Ga_{0.96}As_{0.975}N_{0.02}Sb_{0.005} layer 10b doped with silicon at a concentration of 1×10¹⁹ cm⁻³. The p⁺⁺-type layer 10a is in contact with the underlying p-type multilayer film 7.

The Sb included in both the n⁺⁺- and p⁺⁺-type layers 10b, 10a improves the crystallinity of the tunnel junction layers 10 due to the surfactant effect thereof during the epitaxial growth of the tunnel junction layers 10. The N included in both the n⁺⁺- and p⁺⁺-type layers 10b, 10a reduces the residual strain in the tunnel junction layers 10.

The composition of the TiInGaAsNSb is not necessarily limited to the above composition and may be selected as desired, so long as the Ti component and In component in the III-group elements are selected in the range between 0 and 0.3, and the N component and Sb component in the V-group elements are selected in the range between 0 and 0.05 and between 0 and 0.3, respectively. The reason for limiting to the composition is to reduce the absorption loss of the light having a wavelength of 1.25 μm or longer within the tunnel junction layers to a minimum. The thickness in total of the p⁺⁺- and n⁺⁺-type layers 10a, 10b of the tunnel junction layers 10 is preferably 60 nm or smaller in view of reduction of the absorption loss caused by the carriers.

The reason for inclusion of the Ti as a III-group element in the tunnel junction layers 10 will be described with reference to FIG. 2 showing the relationship between the lattice constant and the bandgap energy in a variety of typical compound semiconductors. The Ti included in the tunnel junction layers 10 while reducing the In content allows the point “A” denoted by open circle on the “InAs curve” in the graph of FIG. 2 to shift to a lower point “B” also denoted by open circle in the graph. More specifically, inclusion of Ti in the InGaAsNSb considerably reduces the bandgap energy without significantly changing the lattice constant of the tunnel junction layers, thereby reducing the difference in the energy level between the valence band of the p⁺⁺-layer 10a and the conduction band of the n⁺⁺-layer 10b. Thus, the inclusion of Ti in the InGaAsNSb advantageously reduces the electric resistance of the tunnel-junction VCSEL device.

The VCSEL device of the present embodiment may be manufactured using the technique generally used for manufacturing the conventional VCSEL devices. For example, the bottom multilayer reflector 3, lower cladding layer 4, upper cladding layer 6, p-type multilayer film 7 and top multilayer semiconductor reflector 11 may be formed using metal-organic chemical vapor deposition (MOCVD), whereas the MQW active layer structure 5 and tunnel junction layers 10 may be formed using molecular beam epitaxy (MBE). During the epitaxial growth of the tunnel junction layers 10, a metallic source may be used each for the Ti, Ga, In and Sb, a metallic source or AsH₃ gas may be used for the Sb, and nitrogen plasma may be used for the N.

The tunnel junction structure employed in the VCSEL device 100 of the present embodiment affords a higher optical output power due to absence of the p-AlGaAs layer which generally causes absorption in the valence band thereof. In addition, the Sb included in both the n⁺⁺- and p⁺⁺-type layers 10b, 10a of the tunnel junction layers 10 improves the crystallinity of, in particular, the p⁺⁺-type layers 10a compared to the conventional tunnel-junction VCSEL device. Further, the N included in both the n⁺⁺- and p⁺⁺-type layers 10b, 10a reduces the residual strain of, in particular, the n⁺⁺-type layer 10b compared to the conventional tunnel-junction VCSEL devices. Thus, the present embodiment provides a VCSEL device having a higher optical output power and a superior long-term reliability.

### Third Embodiment

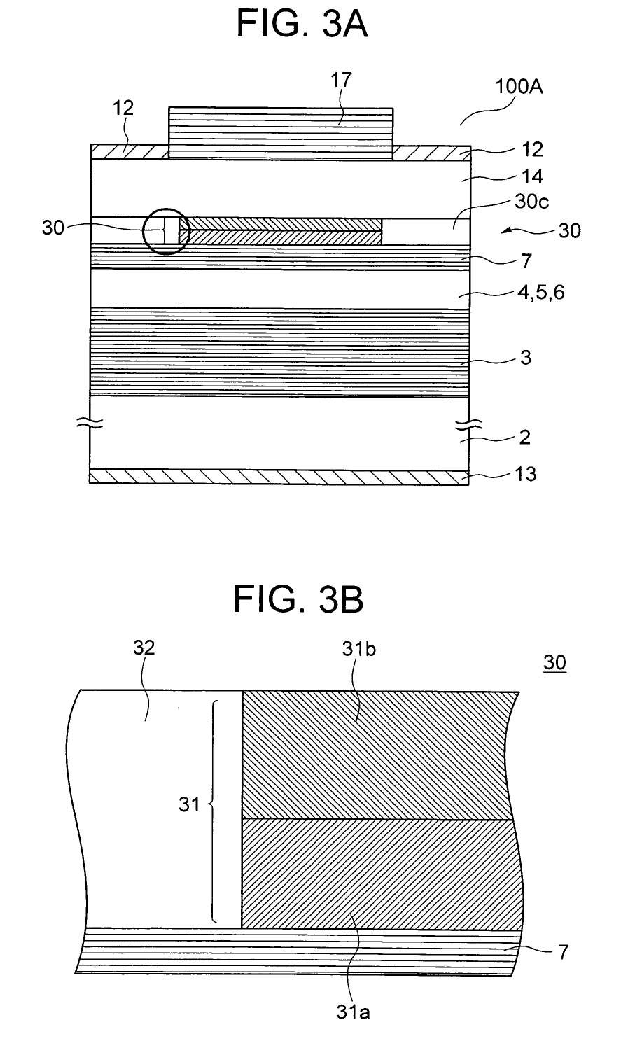

The third embodiment of the present invention is directed to a tunnel-junction VCSEL device having an emission wavelength of 1305 nm. Referring to FIG. 3A, the VCSEL device 100A of the present embodiment includes an n-GaAs substrate 2, and an epitaxial layer structure including an n-type bottom multilayer semiconductor reflector 3, a 126-nm-thick n-GaAs lower cladding layer 4, a MQW active layer structure 5, a 126-nm-thick p-GaAs upper cladding layer 6, a p-type multilayer film 7, a tunnel junction/current confinement structure 30, and an n-GaAs contact layer 14, which are consecutively deposited on the n-GaAs substrate 2. The n-type bottom multilayer reflector 3 includes n-Al_{0.9}Ga_{0.1}As layers and n-GaAs layers each having a thickness of ¼ optical length and alternately deposited in pair to form 35 layer pairs. The MQW active layer structure 5 includes a plurality of 6-nm-thick Ga_{0.67}In_{0.33}N0.01As_{0.99} quantum well (QW) layers and a plurality of GaN_{0.019}As_{0.081} barrier layers each sandwiched between adjacent two of the QW layers. The p-type multilayer film 7 includes p-Al_{0.9}Ga_{0.01}As layers and p-GaAs layers each having a thickness of ¼ optical length and alternately deposited in pair to form two layer pairs. A p-type multilayer dielectric reflector 17 including Si films and SiO₂ films alternately deposited in pair to form three film pairs is formed on the contact layer 14 in the central region thereof. A Cr/Au bottom electrode 13 and a Cr/Au top electrode 12 are formed on the bottom of the n-GaAs substrate 2 and on the contact layer 14, respectively, the Cr/Au top electrode 12 encircling the top multilayer reflector 17.

FIG. 3B shows the detail of the tunnel junction/current confinement structure 30. The tunnel junction/current confinement structure 30 includes a central core region 31 having a higher refractive index and a peripheral cladding region 32 having a lower refractive index and encircling the central core region 31. The core region 31 is configured by tunnel junction layers including a p⁺⁺-In_{0.1}Ga_{0.9}As_{0.945}N_{0.005}Sb_{0.05} layer 31a doped with carbon at a concentration of 1×10²⁰ cm⁻³ and an n-In_{0.06}Ga_{0.94}As_{0.975}N_{0.02}Sb_{0.005} layer 31b doped with silicon at a concentration of 1×10¹⁹ cm⁻³. The p⁺⁺-type 31a layer is in contact with the p-type multilayer film 7. The cladding region 32 is formed of undoped GaAs_{0.985}N_{0.01}Sb_{0.005}.

The Sb included in both the n⁺⁺- and P⁺⁺-type layers 31b, 31a of the tunnel junction layers configuring the core region 31 improves the crystallinity of the tunnel junction layers due to the surfactant effect thereof during the epitaxial growth of the tunnel junction layers, whereas the N included in both the n⁺⁺- and p⁺⁺-type layers 31b, 31a reduces the residual strain of the tunnel junction layers.

The composition of the InGaAsNSb configuring the tunnel junction layers in the core region 31 is not limited to the above composition and may be selected as desired, so long as the In component in the III-group elements is between 0 and 0.3, and the N component and Sb component in the V-group elements are between 0 and 0.05 and between 0 and 0.3, respectively.

The core region 31 configured by the tunnel junction layers suitably passes the current, whereas the cladding region 32 scarcely passes the current due to the undoped material thereof. Thus, the operating current is selectively injected into the core region 31, whereby the core region 31 acts as an emission aperture and the peripheral region 32 acts as a current-blocking area. Thus, the tunnel junction/current confinement structure 30 in the present embodiment has functions of both the core/cladding structure and the current confinement structure.

The core region 31 has a refractive index of 3.5130, and the cladding region 32 has a refractive index of 3.5120, resulting in a refractive-index difference of 0.0010 therebetween. This difference is smaller than the refractive-index difference in the conventional oxidized-confinement structure using an AlₓO_{y} layer, which is generally around 0.0018. This suppresses occurring of higher-order mode lasing to thereby provide a stable single-mode transverse lasing. More specifically, a larger diameter of the emission aperture can be employed in the VCSEL device of the present embodiment for obtaining a higher optical output power while maintaining a single-mode transverse lasing operation.

The VCSEL device 100A of the present embodiment may be manufactured using the technique generally used for manufacturing the conventional VCSEL devices. For example, the bottom multilayer reflector 3, lower cladding layer 4, upper cladding layer 6, and p-type multilayer film 7 may be deposited using metal-organic chemical vapor deposition (MOCVD), whereas the MQW active layer structure 5 and tunnel junction layers 10 may be formed using molecular beam epitaxy (MBE). The multilayer dielectric reflector 17 may be formed using a plasma-enhanced CVD technique.

The upper portion of the epitaxial layer structure including the tunnel junction/current confinement structure 30 may be manufactured, after the step of epitaxially growing the underlying layers including the p-type multilayer film 7, by the steps described hereinafter. The p⁺⁺-In_{0.1}Ga_{0.9}As_{0.945}N_{0.005}Sb_{0.05} layer 31a doped with carbon at a concentration of 1×10²⁰ cm⁻³ and n⁺⁺-In_{0.06}Ga_{0.94}As_{0.975}N_{0.02}Sb_{0.005} layer 31b doped with silicon at a concentration of 1×10¹⁹ cm⁻³ are epitaxially grown using a MBE technique, to thereby form the tunnel junction layers.

Thereafter, the tunnel junction layers 31b, 31a are selectively etched in the peripheral area thereof using a photolithographic and etching technique, thereby leaving the tunnel junction layres in the central core region 31. Subsequently, an undoped GaAs cladding layer is epitaxially grown in the etched peripheral region 32. The n-GaAs contact layer 14 is then grown on the core region 31 and peripheral region 32, followed by forming the multilayer dielectric reflector 17 by using a MBE technique. The multilayer dielectric reflector 17 is then selectively etched in the peripheral region thereof to leave a central circular region to expose the contact layer 14 in the peripheral region. The top electrode 12 is deposited on the exposed, annular peripheral region of the contact layer 14.

The tunnel-junction VCSEL device 100A of the present embodiment achieves the advantages similar to those of the above embodiments. In addition, the tunnel junction layers having a current confinement function suppresses the higher-order mode lasing and thus achieves a superior single-mode transverse lasing operation.

### Fourth Embodiment

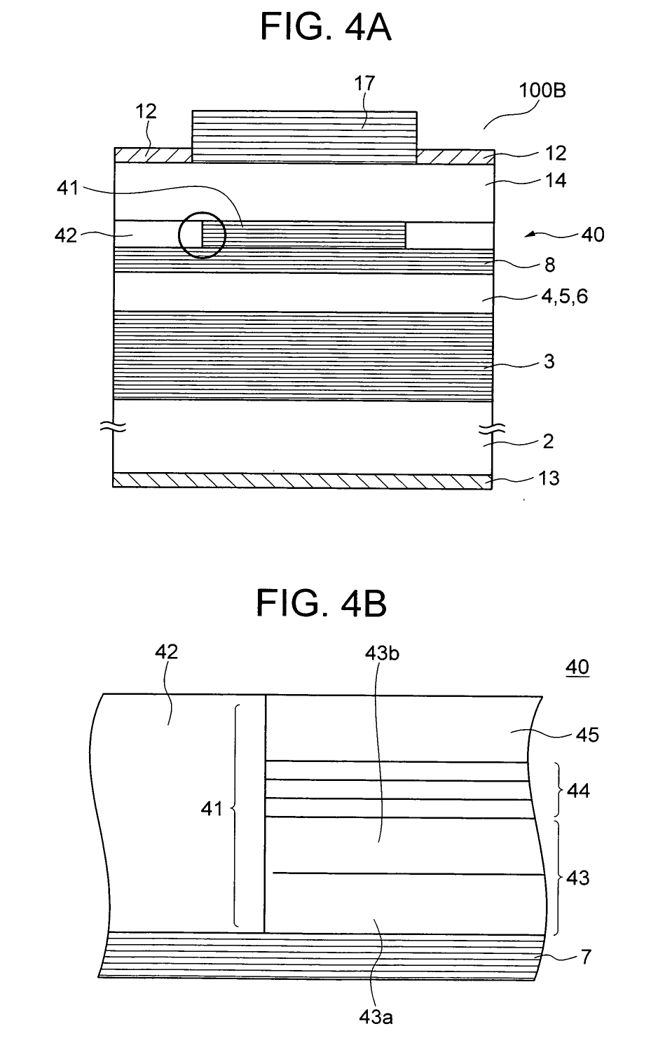

The fourth embodiment of the present invention is directed to a tunnel-junction VCSEL device having an emission wavelength of 1308 nm. Referring to FIG. 4A, the VCSEL device 100B of the present embodiment includes an n-GaAs substrate 2, and an epitaxial layer structure including an n-type bottom multilayer semiconductor reflector 3, a 126-nm-thick n-GaAs lower cladding layer 4, a MQW active layer structure 5, a 126-nm-thick p-GaAs upper cladding layer 6, a p-type multilayer film 7, a tunnel junction/current confinement structure 40, and an n-GaAs contact layer 14, which are consecutively deposited on the n-GaAs substrate 2. The n-type bottom multilayer semiconductor reflector 3 includes n-Al_{0.9}Ga_{0.1}As layers and n-GaAs layers each having a thickness of ¼ optical length and alternately deposited in pair to form 35 layer pairs. The MQW active layer film 5 includes a plurality of 6-nm-thick Ga_{0.67}In_{0.33}N_{0.012}As_{0.988} QW layers and a plurality of GaN_{0.019}As_{0.981} barrier layers. The p-type multilayer film 7 includes p-Al_{0.9}Ga_{0.1}As layers and p-GaAs layers each having a thickness of ¼ optical length and alternately deposited in pair to form two layer pairs. A multilayer dielectric reflector 17 including Si films and SiO₂ films alternately deposited in pair to form three film pairs is formed on the contact layer 14 in the central area thereof. A Cr/Au bottom electrode 13 and a Cr/Au top electrode 12 are formed on the bottom of the n-GaAs substrate 2 and the contact layer 14, respectively, the Cr/Au top electrode 12 encircling the multilayer dielectric reflector 17.

FIG. 4B shows the detail of the tunnel junction/current confinement structure 40. The tunnel junction/current confinement structure 40 includes a central core region 41 having a higher refractive index and a peripheral cladding region 42 having a lower refractive index and encircling the central core region 41. The core region 41 includes, from the bottom thereof, tunnel junction layers 43, a graded-composition film 44, and a refractive-index adjustment layer 45.

The tunnel junction layers 43 include a 10-nm-thick p⁺⁺-In_{0.1}Ga_{0.9}As_{0.945}N_{0.005}Sb_{0.05} layer 43a doped with carbon at a concentration of 1×10²⁰ cm⁻³, and a 30-nm-thick n-In_{0.06}Ga_{0.94}As_{0.975}N_{0.02}Sb_{0.005} layer 43b doped with silicon at a concentration of 1×10⁹ cm⁻³. The p⁺⁺-type layer 43a is in contact with the underlying p-type multilayer film 7

The Sb included in both the n⁺⁺- and P₊₊-type layers 43b, 43a of the tunnel junction layers 43 configuring the core region 41 improves the crystallinity of the tunnel junction layers 43 due to the surfactant effect during the epitaxial growth of the tunnel junction layers 43, whereas the N included in both the n⁺⁺- and p⁺⁺-type layers 43b, 43a reduces the residual strain of the tunnel junction layers 43.

The refractive-index adjustment layer 45 is formed of a 25-nm-thick n-In_{0.52}Ga_{0.48}P. The graded-composition film 44 includes three GaAsP layers having different compositions which reside between the compositions of the underlying In_{0.06}Ga_{0.94}As_{0.975}N_{0.02}Sb_{0.005} layer 43b and the overlying In_{0.52}Ga_{0.48}P layer 45 to moderately change the composition from the underlying layer 43b to the overlying layer 45. The cladding region 42 is formed of undoped GaAs.

The composition of n⁺⁺- and p⁺⁺-layers 43b, 43a of the tunnel junction layers 43 is not limited to the above composition, and may be selected as desired so long as the In component in the III-group elements is between 0 and 0.3, and the N component and Sb component in the V-group elements are between 0 and 0.05 and between 0 and 0.3.

The core region 41 having a tunnel junction structure suitably passes the current therethrough whereas the cladding region 42 scarcely passes the current due to the undoped material thereof, whereby the operating current is selectively injected into the core region 41 during operation of the VCSEL device 100B, similarly to the third embodiment.

The refractive-index adjustment layer 45 reduces the overall refractive-index of the core region 41 to reduce the refractive-index difference between the core region 41 and the cladding region 42. The refractive-index difference can be adjusted by selecting the thickness of the refractive-index adjustment layer 45. For example, a thickness of 25 nm for the refractive-index adjustment layer 45 adjusts the overall refractive index of the core region 41 down to 3.1540, against the refractive index of 3.1532 in the cladding region 42, thereby providing a refractive-index difference of 0.0008 therebetween. The refractive-index difference as small as 0.0008 in the present embodiment, which is smaller compared to the third embodiment having no refractive-index adjustment layer, further suppresses occurring of the higher-order mode lasing to provide a stable single-mode transverse lasing operation. Thus, a larger diameter of the aperture can be employed in the present embodiment to achieve a higher optical output power while maintaining a single-mode transverse lasing operation.

The VCSEL device 100B of the present embodiment can be manufactured similarly to the above embodiments except for the tunnel junction/current confinement structure 40 of the present embodiment. The upper portion of the epitaxial layer structure including the tunnel junction/current confinement structure 40 is manufactured as follows. After depositing the underlying portion of the layer structure up to the p-type multilayer film 7, a p⁺⁺-In_{0.1}Ga_{0.9}As_{0.945}N_{0.005}Sb_{0.05} layer doped with carbon at a concentration of 1×10²⁰ cm⁻³ and an n⁺⁺-In_{0.06}Ga_{0.94}As_{0.975}N_{0.02}Sb_{0.005} layer doped with silicon at a concentration of 1×10¹⁹ cm⁻³ are grown using a MBE technique to configure tunnel junction layers. Subsequently, the n-In_{0.52}Ga_{0.48}P refractive-index adjustment layer 33 and three-layer GaAsP graded-composition film 45 are grown thereon.

The tunnel junction layers 33, graded-composition film 44 and refractive-index adjustment layer 45 are selectively etched using an ordinary photolithographic and etching technique to leave a central portion thereof as a core region 41. Subsequently, an undoped cladding layer is deposited on the periphery of the core region 41 to form the cladding region 42. The n-GaAs contact layer 14 is then deposited on the core region 41 and cladding region 42, followed by depositing the top multilayer dielectric reflector 17 by using a plasma-enhanced CVD technique. The multilayer dielectric reflector 17 is selectively etched to leave the central portion thereof and expose an annular portion of the underlying contact layer 14. The top electrode 12 is formed on the exposed portion of the contact layer 14.

The VCSEL device 100B of the present embodiment achieves advantages similar to those achieved by the above embodiments. In addition, the graded-composition film further provides a more stable operation for the single-mode transverse lasing compared to the third embodiment.

### Fifth Embodiment

The fifth embodiment of the present invention is directed to a tunnel-junction VCSEL device having an emission wavelength of 1310 nm. The VCSEL device of the present embodiment is similar to the fourth embodiment except for the materials for the graded-composition film and refractive-index adjustment layer, and thus will be described with reference to FIGS. 4A and 4B.

In FIG. 4A, the VCSEL device 100B of the present embodiment includes an n-GaAs substrate 2, and an epitaxial layer structure including an n-type bottom multilayer reflector 3, a 126-nm-thick n-GaAs lower cladding layer 4, a MQW active layer structure 5, a 126-nm-thick p-GaAs upper cladding layer 6, p-type multilayer film 7, a tunnel junction/current confinement structure 40, and an n-GaAs contact layer 14, which are consecutively deposited on the n-GaAs substrate 2. The n-type bottom multilayer reflector 3 includes n-Al_{0.9}Ga_{0.1}As layers and n-GaAs layers each having a thickness of ¼ optical length and alternately deposited in pair to form 35 layer pairs. The MQW active layer film 5 includes a plurality of 6-nm-thick Ga_{0.66}In_{0.34}N_{0.012}As_{0.988} QW layer and a plurality of GaN_{0.019}As_{0.081} barrier layers. The p-type multilayer film 7 includes p-Al_{0.9}Ga_{0.1}As/p-GaAs each having a thickness of ¼ optical length and alternately deposited in pair to form two layer pairs. A p-type multilayer reflector 17 including Si films and SiO₂ films alternately deposited in pair to form three film pairs is formed on the contact layer 14 in the central area thereof. A Cr/Au bottom electrode 13 and a Cr/Au top electrode 12 are formed on the bottom of the n-GaAs substrate 2 and on the contact layer 14, respectively, the top electrode 12 encircling the p-type multilayer reflector 14.

In FIG. 4B, the tunnel junction/current confinement structure 40 includes a central core region 41 having a higher refractive index and a peripheral cladding region 42 having a lower refractive index and encircling the central core region 41. The core region 41 includes a tunnel junction layers 43, a graded-composition film 44, and a refractive-index adjustment layer 45.

The tunnel junction layers 43 include a 10-nm-thick p⁺⁺-In_{0.1}Ga_{0.9}As_{0.945}N_{0.005}Sb_{0.05} layer 43a doped with carbon at a concentration of 1×10²⁰ cm⁻³, and a 30-nm-thick n-In_{0.06}Ga_{0.94}As_{0.975}N_{0.02}Sb_{0.005} layer 43b doped with silicon at a concentration of 1×10¹⁹ cm⁻³. The p⁺⁺-type layer 43a is in contact with the p-type multilayer film 7

The Sb included in both the n⁺⁺- and P⁺⁺-type layers 43b, 43a of the tunnel junction layers 43 configuring the core region 41 improves the crystallinity of the tunnel junction layers 43 due to the surfactant effect during the epitaxial growth of the tunnel junction layers 43, whereas the N included in both the n⁺⁺- and p⁺⁺-type layers 43b, 43a reduces the residual strain of the tunnel junction layers 43.

The refractive-index adjustment layer 45 is formed of a 35-nm-thick n-GaAs_{0.98}P_{0.02}. The graded-composition film 44 includes three InGaAsNSbP layers having different compositions which reside between the compositions of the underlying In_{0.06}Ga_{0.94}As_{0.975}N_{0.02}Sb_{0.005} layer 43b and the overlying GaAs_{0.98}P_{0.02} layer 45 to moderately change the composition from the underlying layer 43b to the overlying layer 45. The cladding region 42 is formed of undoped GaAs.

The composition of n⁺⁺- and p⁺⁺-layers 43b, 43a of the tunnel junction layers 43 is not limited to the above composition, and may be selected as desired so long as the In component in the III-group elements is between 0 and 0.3, and the N component and Sb component in the V-group elements are between 0 and 0.05 and between 0 and 0.3, respectively.

The core region 41 having a tunnel junction structure suitably passes the current therethrough whereas the cladding region 42 scarcely passes the current due to the undoped material thereof, whereby the operating current is selectively injected into the core region 41 during operation of the VCSEL device 100B, similarly to the fourth embodiment.

The refractive-index adjustment layer 45 reduces the overall refractive index of the central region 41 to reduce the refractive-index difference between the core region 41 and the cladding region 42. For example, the overall refractive index of the core region 41 is 3.1545, against the refractive index of 3.1538 in the cladding region 42, thereby providing a refractive-index difference of 0.0007 therebetween. The refractive-index difference as small as 0007 in the present embodiment, which is smaller compared to the third embodiment having no refractive-index adjustment layer 45, further suppresses occurring of the higher-order mode lasing to provide a stable single-mode transverse lasing. Thus, a larger diameter of the aperture can be employed in the present embodiment to achieve a higher optical output power while maintaining a single-mode transverse lasing operation.

The VCSEL device 100B of the present embodiment can be manufactured similarly to the above embodiments except for the tunnel junction/current confinement structure 40. The upper portion of the epitaxial layer structure including the tunnel junction/current confinement structure 40 is manufactured as follows. After depositing the underlying portion of the epitaxial layer structure up to the p-type multilayer film 7, a p⁺⁺-In_{0.1}Ga_{0.9}As_{0.945}No_{0.005}Sb_{0.05} layer doped with carbon at a concentration of 1×10²⁰ cm⁻³ and an n⁺⁺-In_{0.06}Ga_{0.94}As_{0.975}N_{0.02}Sb_{0.005} layer doped with silicon at a concentration of 1×10¹⁹ cm⁻³are grown using a MBE technique to configure tunnel junction layers. Subsequently, the three-layer InGaNAsP graded-composition film 44 and the n-InGa_{0.98}P_{0.02} refractive-index adjustment layer 45 are grown thereon.

The tunnel junction layers 43, graded-composition film 44 and refractive-index adjustment layer 45 are selectively etched using an ordinary photolithographic and etching technique to leave a central portion thereof as a core region 43. Subsequently, an undoped cladding layer is deposited on the periphery of the core region 43 to form the annular cladding region 42. The n-GaAs contact layer 14 is then deposited on the core region 41 and cladding region 42, followed by depositing the top multilayer dielectric reflector 17 by using a plasma-enhanced CVD technique. The multilayer dielectric reflector 17 is selectively etched to leave the central portion thereof and expose an annular portion of the underlying contact layer 14. The top electrode 12 is formed on the exposed portion of the contact layer 14.

The VCSEL device 100B of the present embodiment achieves advantages similar to those achieved by the fourth embodiment.

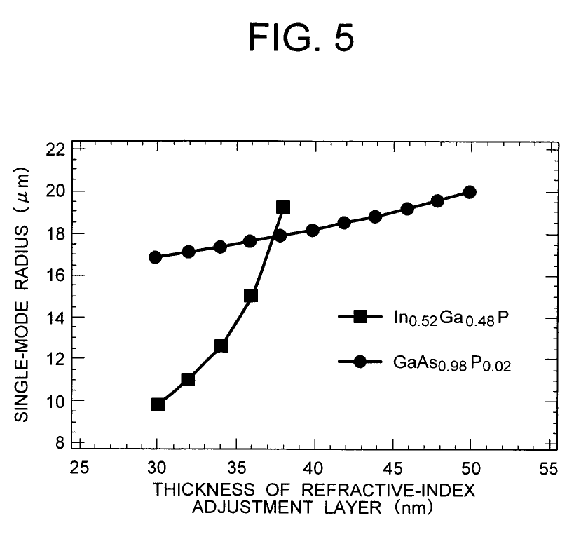

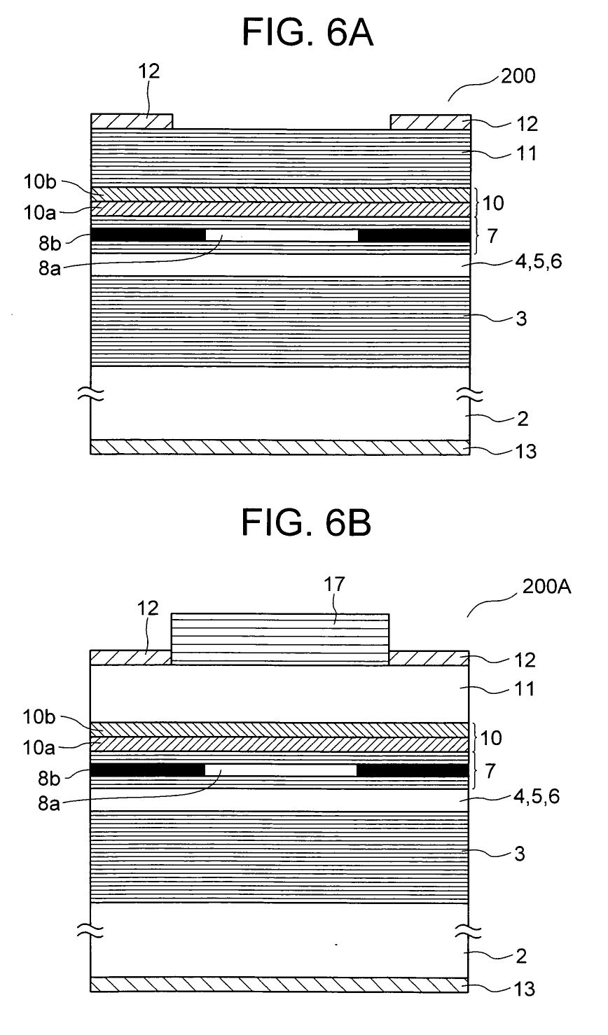

Hereinafter, the GaAs_{0.98}P_{0.02} refractive index adjustment layer used in the fifth embodiment will be compared with the In_{0.52}Ga_{0.48}P refractive-index adjustment layer used in the fourth embodiment. FIG. 5 shows the relationship obtained by calculation between the thickness of the refractive-index adjustment layer 45 and the single-mode radius thereof for the case of using the GaAs_{0.98}P_{0.02} and In_{0.52}Ga_{0.48}P refractive-index adjustment layers. The term “single-mode radius” as used herein means the maximum radius among the radii of the core region in which a single-mode lasing is obtained at a specific injected current. As understood from FIG. 5, the GaAs_{0.98}P_{0.02} provides a more moderate change compared to the In_{0.52}Ga_{0.48}P for the single-mode radius with respect to the change of the thickness of the refractive-index adjustment layer. This achieves suppression of variation in the single-mode radius if the thickness of the refractive-index adjustment layer varies due to the process conditions. It is to be noted that for the case of manufacturing a plurality of VCSEL devices from a single wafer, the GaAs_{0.98}P_{0.02} providing a smaller degree of variation in the single-mode radius achieves a higher product yield for the VCSEL devices.

The materials for the components, such as for the multilayer reflector, used in the above embodiments are only for examples, and thus not limited to those in the embodiments. The multilayer reflector may be formed of any of p-type, n-type, undoped and dielectric layers.

The above embodiments are directed to 1.3-μm-range VCSEL devices; however, the present invention can be directed to other-wavelength-range VCSEL devices such as 0.85-μm-range or above VCSEL devices. In such a wavelength range, the materials for the active layer structure, multilayer reflector etc. should be selected for a desired wavelength range. The MQW active layer structure may be replaced by a SQW (single-QW) layer structure or a single active layer.

1. A vertical cavity surface emitting semiconductor laser (VCSEL) device comprising a GaAs substrate, and a layer structure including a bottom multilayer reflector, an active layer, and a top multilayer reflector consecutively deposited on said GaAs substrate,
said layer structure further including tunnel junction layers including a heavily-doped n-type Tiₓ₂Inₓ₁Ga₁₋ₓ₁₋ₓ₂As_{1-y1-y2}N_{y1}Sb_{y2} mixed-crystal layer and a heavily-doped p-type Tiₓ₄Inₓ₃Ga₁₋ₓ₃₋ₓ₄As_{1-y3-y4}N_{y3}Sb_{y4} mixed-crystal layer, where 0≦x2≦0.3, 0≦x1≦0.3, 0<y1≦0.05, 0<y2≦0.3, 0≦x4≦0.3, 0≦x3≦0.05, 0<y3≦0.05, and 0<y4≦0.3.

2. The VCSEL device according to claim 1, wherein at least one of layers in said bottom multilayer reflector and said top multilayer reflector is an undoped semiconductor layer.

3. The VCSEL device according to claim 1, wherein at least one of layers in said bottom multilayer reflector and said top multilayer reflector is a dielectric layer.

4. The VCSEL device according to claim 1, wherein said active layer has an emission wavelength of not smaller than 0.85 μm.

5. A vertical cavity surface emitting semiconductor laser (VCSEL) device comprising a GaAs substrate, and a layer structure including a bottom multilayer reflector, an active layer, a current confinement layer and a top multilayer reflector consecutively deposited on said GaAs substrate,
said current confinement layer including a light-emitting aperture and a current-blocking region encircling said light-emitting aperture, said light-emitting aperture including tunnel junction layers including a heavily-doped n-type layer and a heavily-doped p-type layer, wherein a difference in an effective refractive index between said light-emitting aperture and said current-blocking region is equal to or below 0.5.

6. The VCSEL device according to claim 5, wherein said heavily-doped n-type layer includes a Tiₓ₂Inₓ₁Ga₁₋ₓ₁₋ₓ₂As_{1-y1-y2}N_{y1}Sb_{y2} mixed crystal, said heavily-doped p-type layer includes a Tiₓ₄Inₓ₃Ga₁₋ₓ₃₋ₓ₄As_{1-y3-y4}N_{y3}Sb_{y4} mixed crystal, and said current-blocking region includes GaAs_{1-y5-y6}N_{y5}Sb_{y6}, where 0≦x2≦0.3, 0≦x1≦0.3, 0<y1≦0.05, 0<y2≦0.3, 0≦x4≦0.3, 0≦x3≦0.05, 0<y3≦0.05, 0<y4<0.3, 0≦y5≦0, and 0≦y6≦0.3.

7. The VCSEL device according to claim 6, wherein said light-emitting aperture further includes a graded-composition layer and a refractive-index adjustment layer consecutively deposited on said tunnel junction layers, said graded-composition layer includes Al_{z1}Ga_{1-z1}As_{1-w1-w2-w3}N_{w1}Sb_{w2}P_{w3} mixed crystal, and said refractive-index adjustment layer includes In_{z3}Ga_{1-z3}P mixed crystal, where 0≦z1≦0.6, 0≦w1≦0.05, 0≦w2≦0.3, 0≦w3≦0.8, and 0.3≦z3≦0.7.

8. The VCSEL device according to claim 5, wherein said light-emitting aperture further includes a graded-composition layer and a refractive-index adjustment layer consecutively deposited on said tunnel junction layers, said graded-composition layer includes In_{z1}Ga_{1-z1}As_{1-w1-w2-w3}N_{w1}Sb_{w2}P_{w3} mixed crystal, and said refractive-index adjustment layer is includes GaAs_{1-w4}P_{w4} mixed crystal, where 0≦z1≦0.3, 0≦w1≦0.05, 0≦w2≦0.3, 0≦w3≦0.8, and 0≦w4≦0.5.

9. The VCSEL device according to claim 5, wherein at least one of layers in said bottom multilayer reflector and said top multilayer reflector is an undoped semiconductor layer.

10. The VCSEL device according to claim 5, wherein at least one of layers in said bottom multilayer reflector and said top multilayer reflector is a dielectric layer.

11. The VCSEL device according to claim 5, wherein said active layer has an emission wavelength of not smaller than 0.85 μm.
